(19) United States
(12) Patent Application Publication
(10) Pub. No.: US 2019/0126495 A1
(43) Pub. Date: May 2, 2019

(54) SAMPLE CONVEYING MEMBER

(71) Applicant: KYOCERA Corporation, Kyoto-shi, Kyoto (JP)

(72) Inventors: Yasunori KAWANABE, Kirishima-city (JP); Yuusaku ISHIMINE, Satsumasendai-city (JP)

(21) Appl. No.: 16/095,801

(22) PCT Filed: Apr. 27, 2017
(86) PCT No.: PCT/JP2017/016726

§ 371 Date: Oct. 23, 2018

(30) Foreign Application Priority Data
Apr. 27, 2016 (JP) 2016-089437

(51) Int. Cl. B25J 15/06; H01L 21/677; C04B 35/111

(52) U.S. Cl. CPC B25J 15/06; C04B 35/111; H01L 21/677

(57) ABSTRACT

The sample conveying member of the present disclosure includes: a ceramic substrate; a support part that includes a conductive member on at least a portion of a sample support surface; and a conductive layer that is positioned inside of the substrate and connects to a grounding unit outside of the substrate from the conductive member.

### TECHNICAL FIELD

The present disclosure relates to a sample conveying member.

### BACKGROUND ART

A silicon epitaxial wafer, which is one type of semiconductor wafer used in Central Processing Units (CPU), flash memory of Microprocessor Units (MPU), and the like, is obtained by causing vapor phase growth of a silicon epitaxial layer on a surface of a silicon monocrystalline substrate. This type of vapor phase growth is carried out, for example, using a single-wafer type vapor phase growth device. This single-wafer type vapor phase growth device processes silicon monocrystalline substrates by one wafer at a time. Furthermore, a single-wafer type vapor phase growth device internally includes: a susceptor on which a silicon monocrystalline substrate is placed; a reaction chamber in which a heating means such as a halogen lamp is arranged in the surrounding area; and a sample conveying member configured to convey a silicon monocrystalline substrate onto the susceptor and to convey to the outside from the reaction chamber a silicon epitaxial wafer after the completion of a vapor phase growth treatment (hereinafter, in some cases, the silicon monocrystalline substrate and the silicon epitaxial wafer are mentioned altogether as a sample).

Here, static electricity is generated through contact when a sample is conveyed inward and when a sample is conveyed outward, and when a sample becomes electrified by this static electricity, in some cases floating particles (granules) are drawn towards the sample and adhered thereto and create contamination.

Therefore, to enable the elimination of static electricity through a sample conveying member, Patent Literature 1, for example, proposes a conveying arm includes: a holding part made from an insulator and configured to contact and hold a substrate; a grounding unit that is grounded and is made from a conductor; and a conducting section that contacts the substrate and the grounding unit and is made from a conductor.

### CITATION LIST

### Patent Literature

Patent Document 1: JP 2013-212920 A

### SUMMARY OF INVENTION

The sample conveying member of the present disclosure includes: a ceramic substrate; a support part that includes a conductive member on at least a portion of a sample support surface; and a conductive layer that is positioned inside of the substrate and connects to a grounding unit outside of the substrate from the conductive member.

### BRIEF DESCRIPTION OF DRAWINGS

FIG. 1 is a plan view illustrating an example of a sample conveying member of the present disclosure.

FIG. 2 is a cross-sectional view along a line A-A′ in FIG. 1.

FIG. 3 is a cross-sectional view along a line B-B′ in FIG. 1.

FIG. 4 is another example of a cross-sectional view along the line B-B′ in FIG. 1.

FIG. 5 is an enlarged view of a section S illustrated in FIG. 4.

FIG. 6 is a plan view illustrating another example of a sample conveying member of the present disclosure.

FIG. 7 is a cross-sectional view along a line C-C′ in FIG. 6.

FIG. 8 is a cross-sectional view along a line D-D′ in FIG. 6.

FIG. 9 is a plan view illustrating an example of a sample processing device including a sample conveying member of the present disclosure.

### DESCRIPTION OF EMBODIMENT

In recent years, wiring formed on silicon epitaxial wafers has been undergoing a trend of miniaturization, directed at higher performance of CPUs and MPU flash memory, etc. In association with the miniaturization of wiring in this manner, a concern about the occurrence of problems such as disconnected or missing wiring when even a small amount of particles become adhered is increasing. Therefore, it is required that adhesion of particles to the silicon monocrystalline substrate before processing and to the silicon epitaxial wafer after processing (hereinafter, these are described collectively as merely samples in some cases) be minimal. To achieve this, the sample conveying member itself must not easily produce particles and the sample conveying member must be capable of eliminating static electricity that is generated through contact when conveying samples inward and outward.

The sample conveying member of the present disclosure does not easily produce particles themselves and is also capable of eliminating static electricity. Hereinafter, the sample conveying member of the present disclosure is described in detail with reference to the drawings.

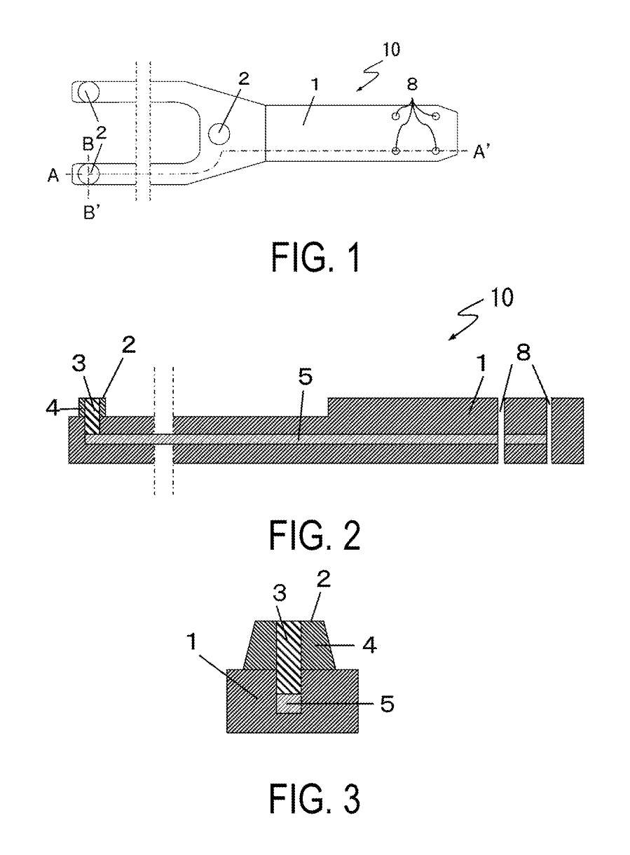

As illustrated by FIG. 1 and FIG. 2, a sample conveying member 10 of the present disclosure includes: a substrate 1; a support part 4 that includes a conductive member 3 on at least a portion of a sample support surface 2; and a conductive layer 5 that is positioned inside of the substrate 1 and connects to a grounding unit outside of the substrate 1 from the conductive member 3. Here, the sample support surface 2 means a surface that contacts a sample, or that faces a sample at a distance of 10 μm or less.

Furthermore, the substrate 1 of the sample conveying member 10 of the present disclosure is made from ceramic. Ceramic is highly durable and corrosion resistant and does not easily produce particles even when used in an atmosphere containing highly corrosive gas and under high temperature and high humidity conditions. Furthermore, the sample conveying member 10 of the present disclosure can eliminate static electricity that is generated when contact occurs between a sample and the support surface 2 by releasing the static electricity from the conductive member 3 on the support surface 2 to the grounding unit through the conductive layer 5. In this manner, the sample conveying member 10 of the present disclosure does not easily produce particles themselves and is also capable of eliminating static electricity.

Note that in FIG. 1, an example of the sample conveying member 10 is illustrated. The sample conveying member 10 has connection holes 8 in four places for connecting to a metal shaft of a sample conveying device (not illustrated) with bolts. Furthermore, the conductive layer 3 and the sample conveying device are to be connected through these bolts and the shaft is to serve as a grounding unit. Also, FIG. 1 illustrates an example of a sample conveying member 10 that includes the substrate 1 having a Y-shape when viewed from a plan view, but the substrate 1 is not limited to a Y-shape and may be another shape such as a rectangular shape, a circular shape, and a trapezoidal shape.

In addition, as the ceramic configuring the substrate 1, ceramics such as aluminum oxide-based ceramics, zirconium oxide-based ceramics, silicon nitride-based ceramics, aluminum nitride-based ceramics, silicon carbide-based ceramics, and mullite-based ceramics can be used. Here, aluminum oxide-based ceramics are ceramics containing 70 mass % or more of aluminum oxide per 100 mass % of all components constituting the ceramic. Note that the same applies to the other ceramics.

Here, the material of the substrate 1 can be confirmed by the following method. First, the material is measured using an X-ray diffraction device (XRD) and a value for each 2θ (2θ is the diffraction angle) is matched with a JCPDS card. Here, an explanation is provided using, as an example, a case in which the presence of aluminum oxide in the substrate 1 is confirmed through XRD. Next, an ICP emission spectrophotometer (ICP) or a fluorescent X-ray analysis device (XRF) is used to perform a quantitative analysis of aluminum (Al). Furthermore, the Al content measured by ICP or XRF is converted to an aluminum oxide (Al₂O₃) content and if the aluminum oxide content is 70 mass % or greater, the substrate 1 is configured with an aluminum oxide-based ceramic.

The conductive member 3 of the sample conveying member 10 of the present disclosure may be configured by any type of material as long as the conductive member 3 is a member having conductivity. For example, if the conductive member 3 contains 90 mass % or more of platinum per 100 mass % of all components configuring the conductive member 3, because platinum excels in corrosion resistance and oxidation resistance, the sample conveying member 10 can preferably eliminate static electricity over a long period of time even when used in corrosive gas or an oxidizing environment.

In addition, if the conductive member 3 is made from a conductive resin, even if contact with a sample repeatedly occurs, the sample is not easily scratched and therefore the generation of particles from the sample can be suppressed. Here, the conductive resin is preferably a resin such as silicone, polyimide, and polyether ether ketone each containing the resin with a conductive substance such as metal and carbon fibers.

Note that the conductive member 3 configures at least a portion of the support surface 2, but the entire support surface 2 may be configured with the conductive member 3 and the support part 4 may also be the conductive member 3.

Furthermore, the volume resistivity of the conductive member 3 of the sample conveying member 10 of the present disclosure may be from 1 Ω·cm to 10⁹ Ω·cm. If this type of configuration is satisfied, the static electricity of the sample can be eliminated without a discharge phenomenon due to the sudden transfer of static electricity.

Here, the volume resistivity of the conductive member 3 can be measured by the following method. The volume resistivity of the conductive member 3 may be measured by using a commercially available electric resistance measuring instrument (for example, the Hiresta-UXMCP-HT800 from Mitsubishi Chemical Analytech Co., Ltd.) and contacting two needles of the electric resistance measuring instrument against the conductive member 3 exposed at the support surface 2. Note that for a case in which the surface area of the conductive member 3 exposed at the support surface 2 is small and the needles of the electric resistance measuring instrument cannot be made to contact the conductive member 3, the sample conveying member 10 may be cut so as to expose the conductive member 3 and the volume resistivity of the exposed conductive member 3 may then be measured.

The sample conveying member 10 according to the present disclosure may also be configured so that the support part 4 is made from ceramic and the conductive member 3 is arranged such that only a portion configuring the support surface 2 faces the sample. If this type of configuration is satisfied, when the sample is loaded onto the support surface 2, the conductive member 3 is not exposed, all exposed locations of the sample conveying member 10 become ceramic, and therefore the generation of particles by the sample conveying member 10 of the present disclosure is hindered even further.

Note that the support part 4 may be configured of a ceramic that differs from that of the substrate 1, but if the support part 4 is configured of the same ceramic as that of the substrate 1, the thermal expansion coefficients of the support part 4 and the substrate 1 become the same, cracks attributed to a difference in the thermal expansion coefficients are not generated, and therefore use in environments of harsh temperature changes is possible. Here, the support part 4 being configured of the same ceramic as that of the substrate 1 means, for example, that if the substrate 1 is configured from an aluminum oxide-based ceramic, then the support part 4 is also configured from the aluminum oxide-based ceramic.

Furthermore, as illustrated in the cross-sectional view of FIG. 3, the support part 4 may be of a shape such that a width dimension becomes larger, approaching the substrate 1 from the support surface 2. If the support part 4 is of this type of shape, the surface area of the support surface 2 that contacts the sample is small and therefore the likelihood of particles attaching to the sample can be reduced. Also, the surface area contacting the substrate 1 is large and therefore the load applied to the support part 4 by the sample can be stably supported by the substrate 1.

The quantity of support parts 4 may be a quantity such that the sample can be stably supported and as illustrated in FIG. 1, if the quantity is three, the sample can be stably supported with a minimum contact surface area. Examples of arrangements of three support parts 4 include an equilateral triangle arrangement or an isosceles triangle arrangement when each of the support parts 4 is connected by a line.

The conductive layer 5 of the sample conveying member 10 of the present disclosure may be configured by any type of material as long as the conductive layer 5 is a member having conductivity. For example, if the conductive layer 5 contains metal, static electricity received from the conductive member 3 can be quickly released to the grounding unit. Examples of the metal contained in the conductive layer 5 may include metals such as molybdenum (Mo), tungsten (W), and platinum (Pt). In particular, if the conductive layer 5 contains 90 mass % or more of platinum per 100 mass % of all components configuring the conductive layer 5, the electric resistance of the conductive layer 5 becomes smaller and static electricity can be eliminated in a short amount of time.

The conductive layer 5 of the sample conveying member 10 of the present disclosure may also contain ceramic particles. If this type of configuration is satisfied, the rigidity of the conductive layer 5 can be improved and the sample conveying member 10 is not easily vibrated during conveyance. Note that it is preferable that the abovementioned ceramic particles and the ceramic configuring the substrate 1 are the same material, for example, if the ceramic configuring the substrate 1 is an aluminum oxide-based ceramic for example, then the ceramic particles may be aluminum oxide (alumina).

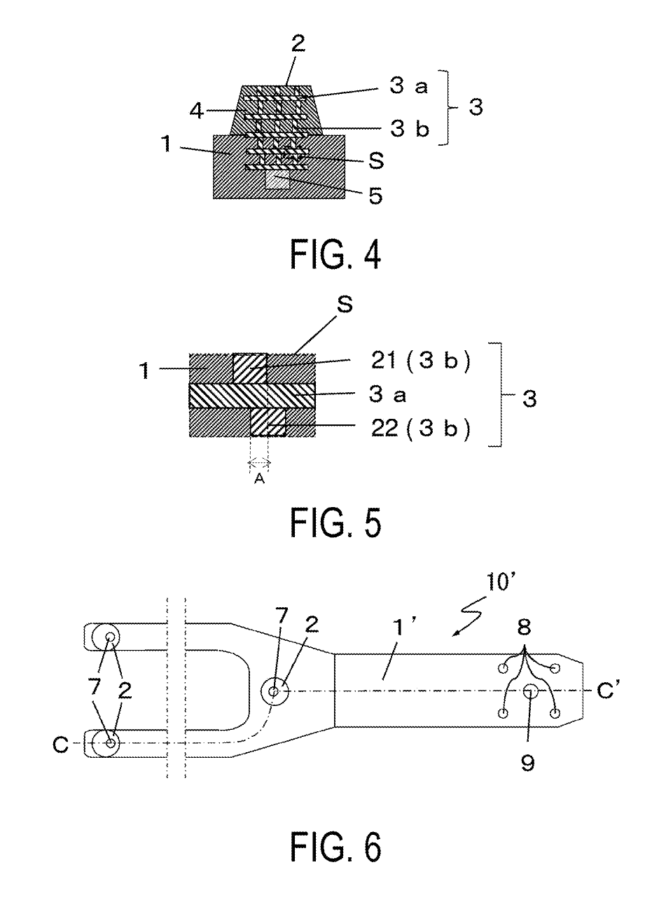

As illustrated in FIG. 4, the conductive member 3 of the sample conveying member 10 of the present disclosure may include: a plurality of first conductors 3a positioned along a direction intersecting the support surface 2; and a plurality of second conductors 3b connecting the plurality of first conductors 3a along the support surface 2. If this type of configuration is satisfied, even if the sample conveying member 10 vibrates in association with conveyance, the stress that is applied to the conductive member 3 by the vibration can be dispersed by each of the second conductors 3b and therefore in comparison to a case like that illustrated by FIG. 3 in which the conductive member 3 is a single pillar shape, disconnections due to stress do not easily occur and the static electricity of the sample can be eliminated for a long period of time. Furthermore, even if one of the plurality of second conductors 3b becomes disconnected, conduction with the first conductors 3a can be maintained by the remaining second conductors 3b that are not disconnected.

Here, the first conductors 3a and the second conductors 3b may be any shape as long as the plurality of second conductors 3b can connect to the first conductors 3a. For example, the first conductor 3a may be a circular plate shape with a thickness from 2 μm to 50 μm and a diameter from 0.5 cm to 2 cm. Also for example, the second conductor 3b may be a columnar shape with a height from 0.2 mm to 2.0 m and a diameter from 50 μm to 700 μm. Note that if the conductive member 3 is a single pillar shape like that illustrated in FIG. 3, the shape is preferably a columnar shape having a diameter from 50 μm to 700 μm.

The quantity of second conductors 3b connecting adjacent first conductors 3a is preferably at least two or more. Furthermore, if the second conductors 3b of the conductive member 3 correspond to a portion configuring the support surface 2, the surface area of the conductive member 3 that is exposed at the support surface 2 can be reduced in comparison to a case in which the first conductors 3a configure the support surface 2 and therefore particle generation can be reduced.

At least one of the substrate 1 and the support part 4 of the sample conveying member 10 of the present disclosure may include a laminated body containing a plurality of plate bodies and each of the first conductors 3a may be positioned between corresponding adjacent plate bodies. If the substrate 1 or the support body 4 is made of a laminated body containing a plurality of plate bodies in this manner, even a complex shape can be easily fabricated by changing, as appropriate, the size of each plate body. In addition, if the first conductors 3a are positioned between adjacent plate bodies, stress can be effectively released when the sample conveying member 10 is vibrated in association with conveyance and the occurrence of disconnection due to stress can be more readily suppressed. Note that both the substrate 1 and the support body 4 may be made of a laminated body containing a plurality of plate bodies.

With respect to the sample conveying member 10 of the present disclosure, as illustrated in FIG. 5, when a portion of the second conductor 3b that is positioned further close to the support surface 2 than the first conductor 3a is considered to be a first site 21 and a portion of the second conductor 3b that is positioned further close to the conductive layer 5 than the first conductor 3a is considered to be a second site 22, vertical lines of respective outer diameters of the first site 21 and the second site 22 may be partially overlapping. Here, the first site 21 of the second conductor 3b is a portion from the first conductor 3a to ½ of the entire length of the second conductor 3b advancing to the support surface 2 and in FIG. 5, the first site 21 is a portion located above the first conductor 3a. On the other hand, the second site 22 of the second conductor 3b is a portion from the first conductor 3a to ½ of the entire length of the second conductor 3b advancing to the conductive layer 5 and in FIG. 5, the second site 22 is a portion located below the first conductor 3a. Furthermore, the matter of vertical lines of the respective outer diameters of the first site 21 and the second site 22 partially overlapping means, as illustrated in FIG. 5, that a width A at which a vertical line of the outer diameter of the first site 21 and a vertical line of the outer diameter of the second site 22 overlap is present. If this type of configuration is satisfied, stress that is applied to the conductive member 3 by vibration can be effectively dispersed by the second conductors 3b.

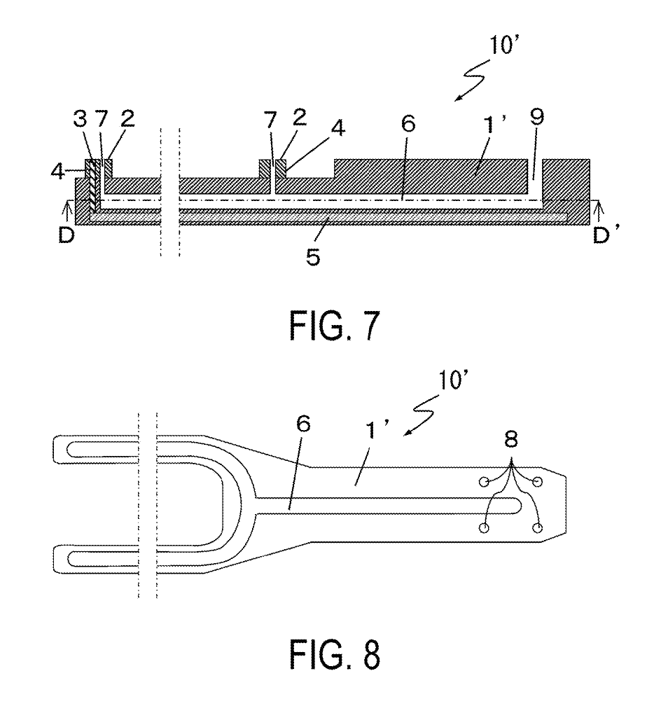

A substrate 1′ of a sample conveying member 10′ of the present disclosure of an example illustrated in FIG. 6 has a flow channel 6 internally and the support part 4 has an air intake port 7 that connects with the flow channel 6 and opens to the support surface 2. Here, as illustrated in FIG. 7, in addition to the air intake hole 7, the flow channel 6 also connects with an exhaust hole 9 having an opening portion in the surface of the substrate 1. In addition, a suction mechanism (not illustrated) that is connected to the opening portion of the exhaust hole 9 is actuated and the sample can be suctioned by the suction force that is generated at this time. The sample can be more stably supported by configuring in this manner.

Note that with respect to the sample conveying member 10′ of the present disclosure, the flow channel 6 may be provided in any manner and the conductive member 3 and the conductive layer 5 do not have to be exposed to an inner surface of the flow channel 6. If this type of configuration is satisfied, the likelihood of particles being generated from the inner surface of the flow channel 6 and the particles passing through the inside of the flow channel 6 and being discharged from the air intake hole 7 is reduced. Therefore, the sample conveying member 10 of the present disclosure becomes a sample conveying member that less easily produces particles. Note that FIG. 8 illustrates an example in which the shape of the flow channel 6 is a Y-shape when viewed from a plan view, but the shape thereof is not limited to a Y-shape and may be any type of shape.

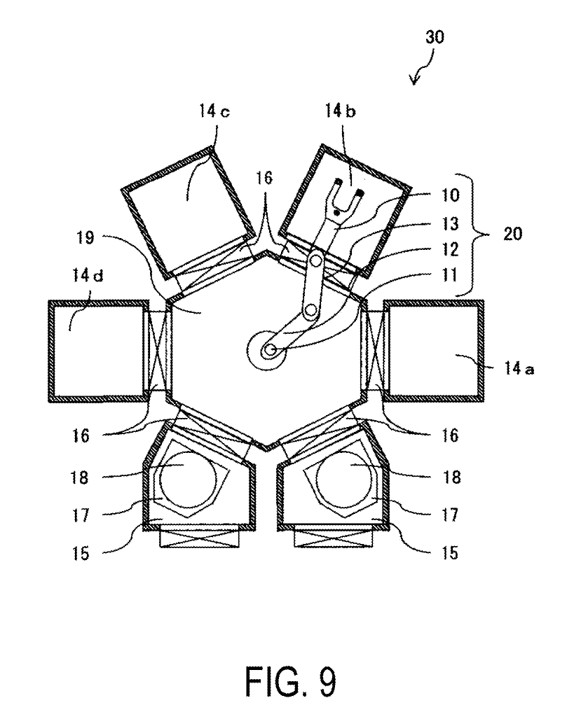

Next, a sample processing device 30 illustrated in FIG. 9 is described as an example of a device including the sample conveying members 10, 10′ of the present disclosure. Note that the reference sign “10” is attached to sample conveying members with respect to FIG. 9 and the following description.

The sample processing device 30 illustrated in FIG. 9 is a multi-chamber type sample processing device 30 configured to continuously process wafers 18 by one wafer at a time. In this sample processing device 30, a sample conveying device 20 is positioned at nearly the center of a conveyance chamber 19. In addition, a plurality of treatment chambers 14a to 14d and two sample cassette chambers 15 each including a sample cassette 17 housing a wafer 18 before or after processing are positioned around the conveyance chamber 19 with respective gate valves 16 interposed.

Here, for example, the following processes are performed at the treatment chambers 14a to 14d respectively. In the treatment chamber 14a, the wafer 18 is subjected to an oxidizing treatment and an oxide film is formed on the surface thereof. In addition, at the treatment chamber 14b, a plasma dry etching device is used to remove the oxide film formed on the wafer 18. At the treatment chamber 14c, an epitaxial treatment is performed to form an epitaxial layer. At the treatment chamber 14d, for example, a layer made from aluminum, titanium, titanium nitride, or the like is formed on the wafer 18 through a sputtering method.

Furthermore, the sample conveying device 20 includes: a shaft 11 that rotates in the axial direction; a first arm 12 rotatably attached to the shaft 11; a second arm 13 likewise rotatably attached to a tip of the first arm 12; and a sample conveying member 10 of the present disclosure, fixed to a tip of the second arm 13.

Moreover, after a gate valve 16 of either of: any of the treatment chambers 14a to 14d; or any of the sample cassette chambers 15 is opened, the sample conveying device 20 extends the second arm 13, causes the sample conveying member 10 to enter the chamber (that is either of: any of the treatment chambers 14a to 14d; or any of the sample cassette chambers 15) and conveys a wafer 18 inward or outward. With this type of sample processing device 30, the sample conveying member 10 of the present disclosure is provided and thereby the likelihood of particles attaching to the wafers 18 in the various treatment processes can be reduced.

Note that the sample conveying member 10 of the present disclosure is not limited to application as a portion of an arm configured to convey a sample as in the above-described sample processing device 30 and may also be used as a member configured to place samples thereon when samples are subjected to a treatment such as lithography or grinding with a device such as a lithography device or a grinding device.

An example of manufacturing the sample conveying member 10 of the present disclosure is described below.

First, predetermined amounts of a sintering aid, binder, solvent and dispersing agent, etc. are added to aluminum oxide, zirconium oxide, silicon nitride, aluminum nitride, silicon carbide, mullite or other such raw material powder and mixed to produce a slurry.

Next, this slurry is used to form a green sheet through the doctor blade method. The slurry is alternatively spray dried and granulated through a spray-granulation method (spray drying method) and a green sheet is then formed through a roll compaction method.

Furthermore, the obtained green sheet is processed using a known method such as a method using laser and a method using metal mold so as to form the green sheet into a desired shape. At this time, through-holes can be formed in the green sheet and a later-described lamination can be performed to thereby make each of these through-holes into the flow channel 6 or a connection hole 8.

Next, a conductive paste having molybdenum, tungsten, platinum, or the like as a main component is prepared and the conductive paste is printed onto the location of the green sheet where the conductive layer 5 is to be formed. At this time, ceramic particles are added to the conductive paste and thereby the conductive layer 5 becomes a layer that contains ceramic particles.

Next, green sheets are laminated through a lamination method and a compact is produced. Note that the above-described slurry may be used as the joining material that is used when the green sheets are laminated.

Furthermore, the substrate 1 including the conductive layer 5 internally can be obtained by firing the obtained compact tailored to the firing conditions of each raw material powder. For cases in which the raw material powder is an oxide, firing is performed in the atmosphere and therefore using a conductive paste that contains platinum, which does not easily oxidize, as the main component is preferable. For cases in which the raw material powder is a non-oxide, firing is performed in a reducing atmosphere or a vacuum atmosphere and therefore using a conductive paste that contains tungsten or molybdenum as the main component is preferable.

Next, the conductive member 3 made from a conductive resin obtained by kneading a metal, carbon fibers, or other such conductive substance into silicone, polyimide, polyether ether ketone, or other such resin is prepared.

Furthermore, this conductive member 3 is disposed so as to configure at least a portion of the support surface 2 and so as to contact the conductive layer 5 and thereby the sample conveying member 10 of the present disclosure is obtained. Note that the conductive member 3 may be bonded through an adhesive with the support part 4 and the substrate 1. Alternatively, the conductive member 3 may be formed into a screw-threaded shape and may be screw-joined with the support part 4 and the substrate 1.

Note that in order to configure the conductive member 3 with the plurality of first conductors 3a positioned along a direction intersecting the support surface 2 and the plurality of second conductors 3b connecting the plurality of first conductors 3a along the support surface 2, the substrate 1 and the support part 4 may be produced by the following method.

First, a plurality of through-holes of any optional shape such as a columnar shape is formed in green sheets, after which these through-holes are filled with the abovementioned conductive paste and a plurality of such green sheets with filled through-holes is prepared. Here, the conductive paste that is filled into the through-holes of the green sheets becomes the second conductors 3b after firing. Next, each of the green sheets is laminated, but at this time, the abovementioned conductive paste is coated onto green sheet(s) in any optional shape such as a circular plate-shape so that the conductive paste that becomes the second conductors 3b for both of two adjacent green sheets is covered. Here, the conductive paste that has been applied becomes the first conductors 3a after firing. Subsequently, the substrate 1 and the support part 4 may be produced by firing.

### REFERENCE SIGNS LIST

### 1, 1′: Substrate

2: Support surface
3: Conductive member
3a: First conductor
3b: Second conductor
4: Support part
5: Conductive layer
6: Flow channel
7: Air intake hole
10, 10′: Sample conveying member

1. A sample conveying member comprising:
a ceramic substrate;
a support part disposed on the ceramic substrate, the support part including a conductive member on at least a portion of a sample support surface of the support part; and
a conductive layer positioned inside of the ceramic substrate, the conductive layer providing a connection from the conductive member to a grounding unit outside of the ceramic substrate.

2. The sample conveying member according to claim 1, wherein the conductive member includes a conductive resin.

3. The sample conveying member according to claim 1, wherein a volume resistivity of the conductive member is from 1 Ω·cm to 10⁹ Ω·cm.

4. The sample conveying member according to claim 1, wherein the support part includes a ceramic; and
the conductive member is arranged such that only a portion configuring the sample support surface faces a sample that is conveyed by the sample conveying member.

5. The sample conveying member according to claim 1, wherein the conductive layer contains ceramic particles.

6. The sample conveying member according to claim 1, wherein the conductive member includes a plurality of second conductors positioned along a direction intersecting the sample support surface; and a plurality of first conductors configured to connect the plurality of second conductors along the sample support surface.

7. The sample conveying member according to claim 6, wherein at least one of the ceramic substrate and the support part includes a laminated body including a plurality of plate bodies, and the plurality of first conductors are positioned between adjacent plate bodies.

8. The sample conveying member according to claim 6, wherein when a portion of a second conductor that is positioned closer to the support surface than a first conductor is a first site, and a portion of a second conductor that is positioned closer to the conductive layer than the first conductor is a second site, and wherein vertical lines of respective outer diameters of the first site and the second site are partially overlapping.

9. The sample conveying member according to claim 1, wherein:
the ceramic substrate includes a flow channel inside of the ceramic substrate; and
the support part includes an air intake port that connects with the flow channel, and that opens to the sample support surface.

10. The sample conveying member according to claim 1, wherein the conductive member includes a plurality of first conductors positioned within the support part and the ceramic substrate along a direction of the sample support surface; and a plurality of second conductors configured to connect the plurality of first conductors along a direction substantially orthogonal to the sample support surface.

11. The sample conveying member according to claim 6, wherein a second conductor A that is connected to first surface of a first conductor and a second conductor B that is connected to second surface opposite the first surface of the first conductor are aligned to partially overlap in the direction substantially orthogonal to the sample support surface.
